(19) United States
(12) Patent Application Publication
(10) Pub. No.: US 2025/0183201 A1
(43) Pub. Date: Jun. 5, 2025

(54) PANEL SCALE PACKAGING OF A PLURALITY OF TRANSFORMER DEVICES FOR REDUCED PARASITIC INDUCTANCE

(71) Applicant: Danger Devices Inc., San Jose, CA (US)

(72) Inventor: Nicholas SUTARDJA, San Jose, CA (US)

(21) Appl. No.: 18/525,149

(22) Filed: Nov. 30, 2023

(51) Int. Cl. H01L 23/64; H01L 21/56; H01L 23/31; H01L 23/538

(52) U.S. Cl. CPC H01L 23/645; H01L 21/561; H01L 23/3107; H01L 23/5386

(57) ABSTRACT

A panel scale packaging apparatus of a plurality of transformer devices. The apparatus has a plurality of die comprising a plurality of transformer devices spatially disposed in a predetermined pattern formed on a portion of the carrier member that has been released to achieve a fill factor of 70 percent and greater overlying the front side surface such that each pair of die are configured with a predetermined pitch between the pair of die. The apparatus has an encapsulating material overlying a surface region of the plurality of die that fills each of the regions defining the pitch to form an upper surface region of encapsulating material overlying an entirety of the plurality of die to seal each die bounded by a portion of the encapsulating material.

### CROSS REFERENCE TO RELATED APPLICATIONS

N/A

### BACKGROUND OF INVENTION

A transformer has been an important component in many electrical and electronic systems. The transformer is a passive device that transfers electrical energy between two or more circuits through electromagnetic induction. Transformers have been widely used in various applications, including power transmission and distribution, electronic devices, and communication systems.

Historically, the concept of the transformer was first introduced by Michael Faraday, who was an early pioneer of electricity and magnetics, in the early 1830s. However, it was not until the late 1800s that practical transformer designs were developed. Pioneering work of William Stanley, Nikola Tesla, and Lucien Gaulard led to the development of efficient transformers suitable for power transmission.

In the context of integrated circuits (ICs), transformers have been primarily used for coupling signals between different circuits, especially in radio frequency (RF), millimeter wave (mmWave), power supply regulation, and high-speed analog and digital applications. Transformers designed for RF or mmWave purposes are typical used for power transfer, impedance matching, coupling, and frequency transformation in RF circuits. RF transformers are commonly found in wireless communication systems, such as transceivers, RF amplifiers, and antenna systems. Transformers are commonly found in switching power supplies, motor drives, and high-speed digital interfaces. Transformers have also played a crucial role in communication systems, enabling signal transmission and isolation.

IC transformers have been predominantly and widely made with two windings: one for the primary turn(s) and another for the secondary turns(s). Each winding has been composed as one or multiple turns, implemented through an offset on the same metal layer or realized by two separate windings on different metal layers. Three winding IC transformers have been shown as well to improve coupling and efficiency, where two of the windings surround the remaining winding. The two windings are connected together at the endpoints, ultimately reducing the structure again to a single primary winding and a single secondary winding transformer.

While transformers offer advantages, they also have drawbacks. Such drawbacks include size and weight, costs, limited frequency range, and power losses, including difficulty to integrated in miniaturized ICs. Specifically, transformers in ICs suffer from increased resistance losses compared to their counterparts when realized with discrete components or physical wire windings. Additionally, conventional packaging for such transformers are often cumbersome, and cause increased parasitics. Despite these drawbacks, IC transformers remain indispensable in various electrical and electronic systems, playing a vital role in power transmission, signal coupling, and isolation. Advancements in transformer technology to address these limitations and improve their overall performance are desired.

### SUMMARY OF INVENTION

According to the present invention, techniques related generally to integrated circuits are provided. In particular, the present invention provides a package device configured for a distributed transformer device and related manufacturing method. Merely by way of example, the invention can be applied to a variety of applications, including RF circuits and designs, mm Wave circuits, power supply regulation and conversion, digital and analog amplifiers and oscillator circuits, communication circuits, and others.

In an example, the present invention provides a panel scale packaging apparatus of a plurality of transformer devices. The apparatus has a plurality of die comprising a plurality of transformer devices spatially disposed in a predetermined pattern formed on a portion of the carrier member that has been released to achieve a fill factor of 70 percent and greater overlying the front side surface such that each pair of die are configured with a predetermined pitch between the pair of die. The apparatus has an encapsulating material overlying a surface region of the plurality of die that fills each of the regions defining the pitch to form an upper surface region of encapsulating material overlying an entirety of the plurality of die to seal each die bounded by a portion of the encapsulating material.

In an alternative example, the invention includes a panel scale packaging apparatus of a plurality of transformer devices. The apparatus has a plurality of die comprising a plurality of transformer devices spatially disposed in a predetermined pattern formed on a portion of the carrier member that has been released to achieve a fill factor of 70 percent and greater overlying the front side surface such that each pair of die are configured with a predetermined pitch between the pair of die. The apparatus has an encapsulating material overlying a surface region of the plurality of die, and filling each of the regions defining the pitch to form an upper surface region of encapsulating material overlying an entirety of the plurality of die to seal each die bounded by a portion of the encapsulating material. The apparatus has a backside surface comprising a portion of a plurality of transformer devices each of which is in die form, and a released portion of the encapsulant material.

Depending upon the example, the present invention can achieve one or more of these benefits and/or advantages. In an example, the present invention provides a novel package design including a transformer configured for use with semiconductor integrated circuits in a compact and spatially efficient system and related methods. In an example, the packaged transformer device and methods can be configured with complementary metal oxide semiconductor (“CMOS”) circuits, and others. In an example, the present invention offers advantages of generating an efficient transformer for manufacture and scalability. These and other benefits and/or advantages are achievable with the present device and related methods. Further details of these benefits and/or advantages can be found throughout the present specification and more particularly below.

A further understanding of the nature and advantages of the Invention may be realized by reference to the latter portions of the specification and attached drawings.

### BRIEF DESCRIPTION OF THE DRAWINGS

In order to more fully understand the present invention, reference is made to the accompanying drawings. Understanding that these drawings are not to be considered limitations in the scope of the invention, the presently described embodiments and the presently understood best mode of the invention are described with additional detail through use of the accompanying drawings in which:

FIG. 1A and FIG. 1B are simplified diagrams of a packaged panel scale device according to an example of the present invention.

FIG. 2A, FIG. 2B, FIG. 3, FIG. 4A, FIG. 4B, AND FIG. 5 are simplified series of diagrams illustrating a method of manufacturing a packaged scale device according to an example of the present invention.

FIGS. 6A and 6B are simplified illustrations of (a) top view multiple die on carrier device and (b) side view of multiple die in a package according to an example of the present invention.

FIGS. 7A and 7B are simplified illustrations of (a) top view of RDL transformer (b) Side view of single track of via region according to an example of the present invention.

FIGS. 8A and 8B are simplified illustrations of (a) top view of IC inductor and package RDL inductor (b) top view of IC transformer and package RDL inductor according to an example of the present invention.

### DETAILED DESCRIPTION OF THE EXAMPLES

The present invention provides a distributed transformer device and a method for integrated circuits. In particular, the present techniques include a package for a distributed transformer device and a related manufacturing method. Merely by way of example, the invention can be applied to a variety of applications, including RF circuits and designs, digital and analog circuits, communications, and others.

In an example, the present invention provides a panel-level packaging (PLP) for a distributed transformer device that involves packaging multiple semiconductor devices on a single large substrate or panel, which is then diced into individual units. This approach enhances efficiency, reduces costs, and enables higher levels of integration.

In an example, the present technique includes one or more of the following panel level packaging process steps:
1. Substrate Preparation: The process begins with the preparation of a large substrate or panel, typically made of a material like glass, silicon, or laminate. This panel acts as the base on which multiple semiconductor devices will be packaged.
2. Die Placement and Attachment: Multiple semiconductor dice (individual integrated circuit chips) are placed onto the panel using automated pick-and-place equipment. Each die contains various components, such as transistors, capacitors, and interconnects, that make up the integrated circuit.
3. Carrier Attachment: To ensure stability and facilitate handling during subsequent processing steps, a temporary carrier is attached to the panel. The carrier is a rigid material that holds the dice in place. It also acts as a support structure while the packaging process progresses.
4. Encapsulant Dispensing: An encapsulant, often an epoxy-based material, is dispensed over the panel to cover the dice and create a protective layer. The encapsulant safeguards the dice from environmental factors such as moisture, dust, and mechanical stress. The encapsulant material is carefully selected to have appropriate thermal, mechanical, and electrical properties to meet the requirements of the packaged devices.
5. Encapsulant Curing: The encapsulant is cured or hardened using heat, UV light, or other curing methods. This step solidifies the encapsulant, creating a robust protective layer around the dice.
6. Interconnect Formation: Interconnects are crucial for providing electrical connections between the packaged dice and external components. This is achieved through various techniques, such as wire bonding, flip-chip bonding, or advanced fan-out wafer-level packaging (FOWLP) technologies. Wire bonding involves connecting the bond pads on the dice to corresponding pads on the substrate using fine wires, while flip-chip bonding involves directly connecting the solder bumps on the dice to the substrate.
7. RDL (Redistribution Layer) Formation: Redistribution layers are added to route signals from the die's original layout to a package layout. This enables more compact and efficient packaging while maintaining necessary connectivity.
8. Underfill Dispensing (Optional): In some examples, an underfill material might be dispensed between the die and the substrate to provide additional mechanical support and protect against thermal stress.
9. Testing and Inspection: Before proceeding further, the packaged dice are tested for functionality, electrical performance, and potential defects. Inspection techniques such as optical inspection, X-ray imaging, and electrical tests are used to ensure the quality of each package.
10. Separation and Singulation: After successful testing, the panel is diced into individual units, each containing one packaged semiconductor die. This singulation process can be achieved through various methods, such as mechanical sawing, laser cutting, or chemical etching.
11. Final Testing and Quality Control: Each singulated package is subjected to final testing to confirm its functionality and performance. Any defective units are identified and removed during this stage.
12. Packaging Completion: The singulated and tested packages are now ready for integration into electronic devices, such as smartphones, computers, or automotive systems.

Panel-level packaging offers several advantages, including higher throughput, reduced manufacturing costs, and improved thermal performance, making it a valuable technique for more efficient and compact devices. Further details of the aforementioned packaging process can be found below.

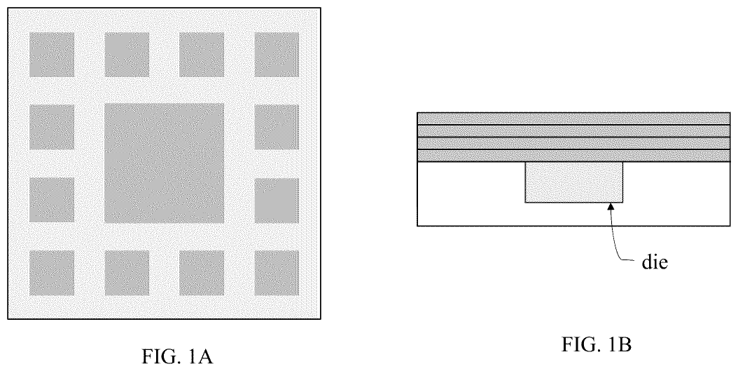

FIG. 1A and FIG. 1B are simplified diagrams of a packaged panel scale device according to an example of the present invention. As shown, the packaged device includes a bottom view and a side view. The bottom view shows a backside contract region, including a plurality of contact regions, each of which is made of a conductive material. The conductive material can be a conductor such as aluminum, copper, or other suitable metals. The packaged device includes a side view of a die encapsulating in an encapsulating material. The die is configured along a backside, including a plurality of redistribution layers, also called RDL.

Further details on manufacturing the packaged device are provided throughout the specification and more particularly below.

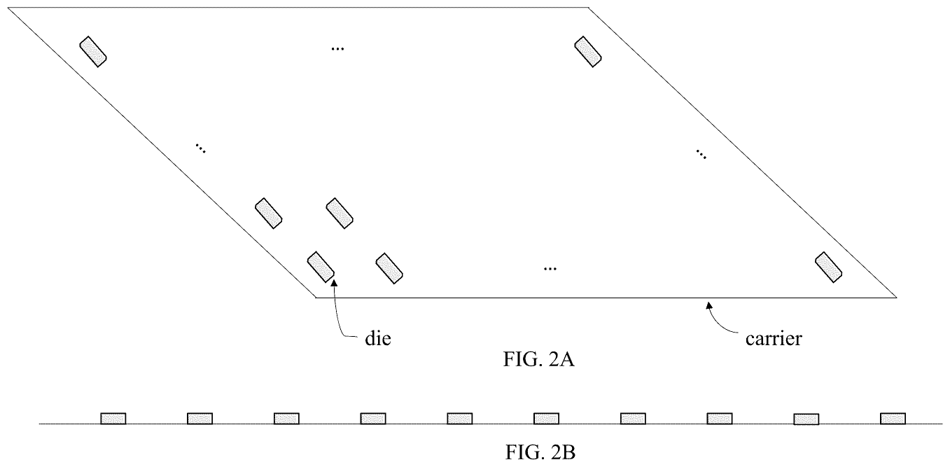

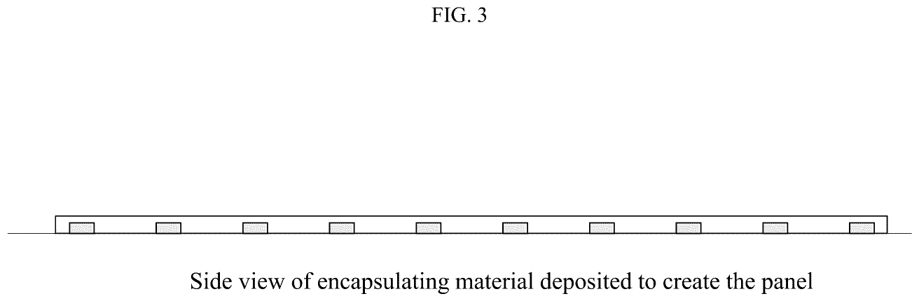

FIG. 2A, FIG. 2B, FIG. 3, FIG. 4A, FIG. 4B, and FIG. 5 are simplified series of diagrams illustrating a method of manufacturing a packaged scale device according to an example of the present invention. In an example, the present invention provides a method for panel scale packaging of a plurality of transformer devices. In an example, the method includes providing a substrate member, such as carrier shown in FIG. 2A. In an example, the substrate member comprises a dielectric material, a first side surface, and a second side surface. The substrate member has a length of at least 500 milli-meters, and is shaped as a trapezoid, but can have other shapes and sizes. In an example, the substrate member is the carrier device.

In an example as shown in FIG. 2B, the method includes spatially disposing a plurality of die comprising a plurality of transformer devices in a predetermined pattern on a portion of the first side surface to achieve a fill factor (e.g., 70 percent and greater) overlying the first side surface such that each pair of die are configured with a predetermined pitch between the pair of die.

In an example, spatially disposing comprises a pick and place operation to move each die one by one from a first location to a location on the first side surface region. In an example,

the plurality of die comprises at least 10,000 die or at least 100,000 die. Of course, there can be variations, alternatives, and modifications.

Referring to FIG. 3, in an example, the method includes forming an encapsulating material overlying a surface region of the plurality of die. The encapsulating material fills each of the regions defining the pitch to form an upper surface region of encapsulating material overlying an entirety of the plurality of die to seal each die bounded by a portion of the encapsulating material and a portion of the substrate member. In an example, the method includes planarizing the upper surface region using a polishing process or a grinding process. In an example, the encapsulating material comprises an epoxy material, a polymer plastic material, a dielectric material, or glass material. The encapsulated structure causes formation of a panel structure encapsulating each of the plurality of die.

In an example, the method includes releasing the substrate member to free the panel structure including the plurality of die. The release exposes a backside of the panel structure to expose a portion of each of the plurality of die, as shown in FIG. 4A. In an example, the method includes forming a plurality of redistribution layers (See FIG. 4B) overlying the backside of the panel structure. The redistribution layers are configured to form an interconnection structure between each of the plurality of die and one or more contact pads configured from the redistribution layers.

In an example, the one or more contact pads comprises one or more solder balls. In an example, the one or more contact pads comprises an overlying dielectric material.

In an example as shown in FIG. 5, the method includes separating each of the packaged components using a saw blade, a scribe and break, or a laser ablation configured to a spacing based upon a package dimension of the die.

In an example, the method includes spatially disposing a plurality of die comprises a low noise amplifier configured on a silicon on insulating substrate onto a portion of the frontside surface.

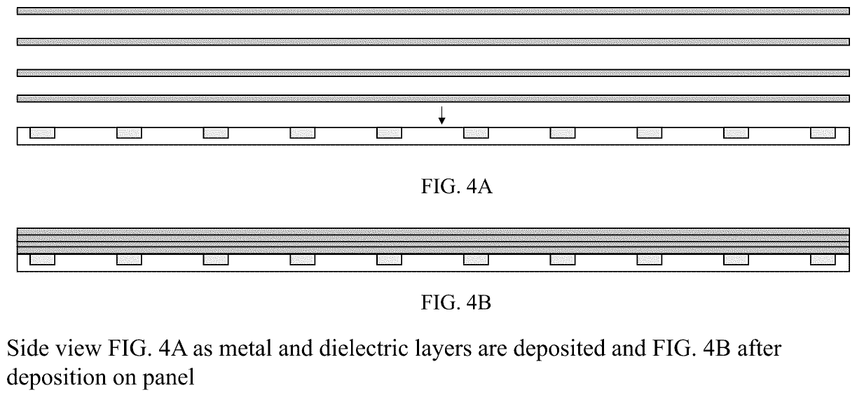

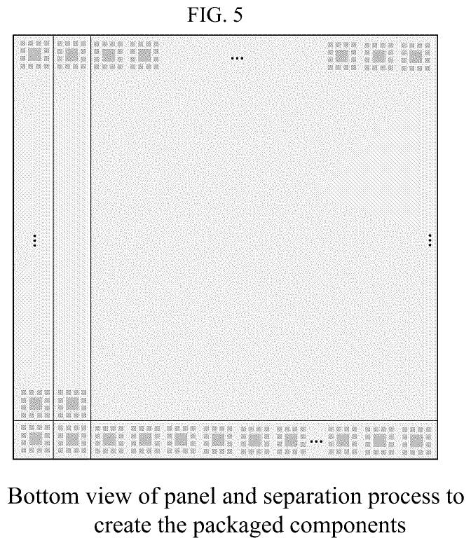

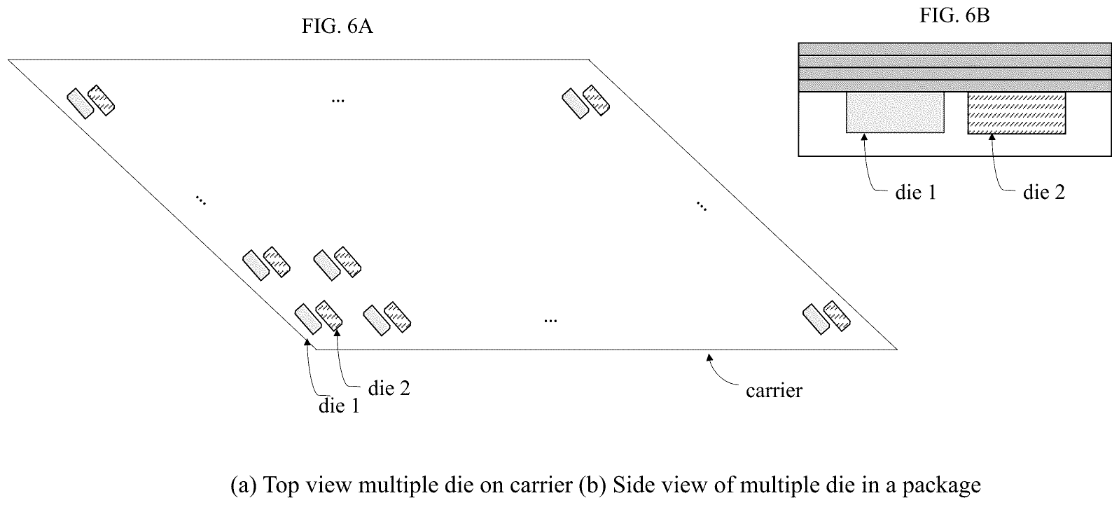

In an example, FIGS. 6A and 6B are simplified illustrations of (a) top view multiple die on carrier device and (b) side view of multiple die in a package according to an example of the present invention. In an example, multiple die each of which is a low noise amplifier can be configured on a carrier device. In an example, spatially disposing a plurality of die comprises a low noise amplifier configured on a silicon on insulating substrate onto a portion of the frontside surface and separating at least one die comprising the low noise amplifier and at least one die comprising the transformer to create a separate co-packaged chip device.

In an example, the invention includes a panel scale packaging apparatus of a plurality of transformer devices. The apparatus has a plurality of die comprising a plurality of transformer devices spatially disposed in a predetermined pattern formed on a portion of the carrier member that has been released to achieve a fill factor of 70 percent and greater overlying the front side surface such that each pair of die are configured with a predetermined pitch between the pair of die. The apparatus has an encapsulating material overlying a surface region of the plurality of die, and filling each of the regions defining the pitch to form an upper surface region of encapsulating material overlying an entirety of the plurality of die to seal each die bounded by a portion of the encapsulating material. The apparatus has a backside surface comprising a portion of a plurality of transformer devices each of which is in die form, and a released portion of the encapsulant material.

The apparatus has a plurality of redistribution layers overlying the backside surface and configured to form an interconnection structure formed between each of the plurality of die and one or more contact pads configured from the redistribution layers.

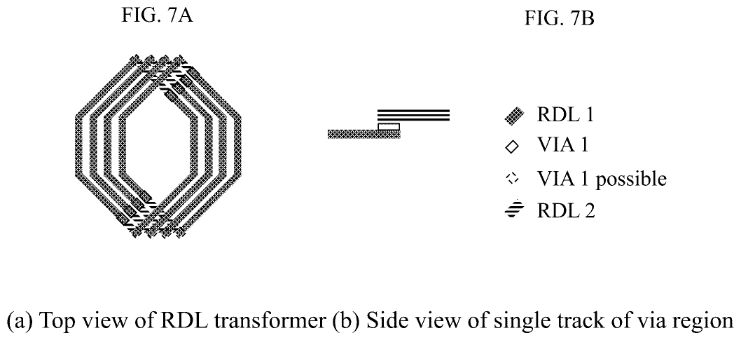

In an example, the apparatus has a plurality of transformer device comprising a plurality of primary tracks and a plurality of secondary tracks configured from a portion of the plurality of redistribution layers. As shown, FIGS. 7A and 7B are simplified illustrations of (a) top view of RDL transformer (b) Side view of single track of via region according to an example of the present invention. A pair or more of conductive layers in the redistribution layers can be configured to form a plurality of transformer devices, as shown.

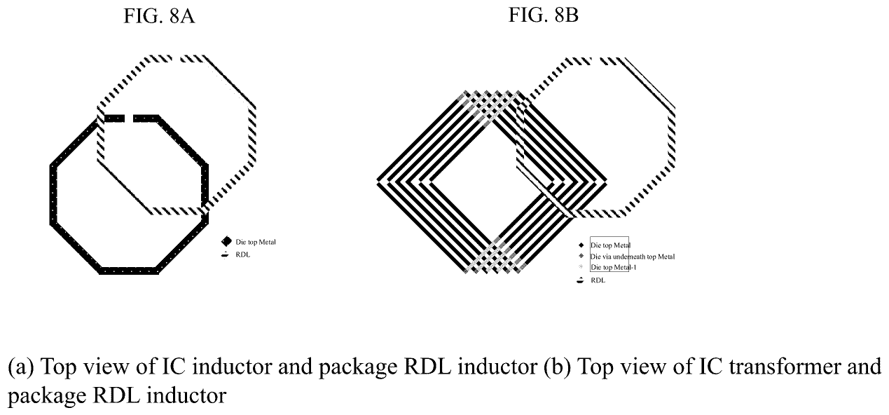

FIGS. 8A and 8B are simplified illustrations of (a) top view of IC inductor and package RDL inductor (b) top view of IC transformer and package RDL inductor according to an example of the present invention. As shown, the illustrations show a combination of transformer devices formed in an integrated circuit chip portion of the substrate and within the redistribution layers.

As shown, the present transformer die is configured directly on one or more of the redistribution layers. The transformer die incudes a novel distributed transformer described in U.S. Ser. No. 18/460,467 filed Sep. 1, 2023, titled “METHOD AND DEVICE FOR DISTRIBUTED TRANSFORMER ON INTEGRATED CIRCUIT CHIP,” (Attorney Docket No. 998RO0001US), commonly assigned, and hereby incorporated by reference for all purposes. Additionally, the distributed transformer in the die is electrically and physically isolated from passive structures on the packaging, reducing or minimizing detrimental influences of electromagnetic fields that may detrimentally couple to the on-die transformers.

By removing a need for bumps between die and package, panel scale packaging reduces distance between the die and package by around 25 um to 60 um compared to traditional flip-chip with bump packaging. Since the panel scale package metal layers are closer to the die compared to how close they would be in a traditional flip-chip with bump packaging techniques, these detrimental influences of electromagnetic fields could be amplified. However, by using a transformer structure on die compared to on-die inductor structures, we mitigate these undesirable coupling effect introduced by closer RDL layers since these transformer devices are tightly coupled.

Although the above has been described in specific shapes and structures, the invention can have variations. That is, the shape can be varied in shape, curved, or formed in other shapes to achieve the invention as described in the claims.

In other examples, each of the tracks has been described in terms of a constant width, however, each of the tracks can be patterned or shaped in different ways according to alternative examples.

While the above is a full description of the specific examples, various modifications, alternative constructions and equivalents may be used. As an example, the distributed transformer device can include any combination of elements described above, as well as outside of the present specification. In an example, the distributed transformer has been described in terms of a generalized configuration but can include multiple tracks, 1, 2, 3, 4 . . . . Nth, and multiple segments, 1, 2, 3, 4 . . . . Mth. Other configurations can also exist depending upon the application. Therefore, the above description and illustrations should not be taken as limiting the scope of the present invention which is defined by the appended claims.

1. A method for panel scale packaging of a plurality of transformer devices, the method comprising:
providing a substrate member, the substrate member comprising a dielectric material, a first side surface and a second side surface, the substrate member having a length of at least 500 milli-meters, and being shaped as a trapezoid;
spatially disposing a plurality of die comprising a plurality of transformer devices in a predetermined pattern on a portion of the first side surface to achieve a fill factor of 70 percent and greater overlying the first side surface such that each pair of die are configured with a predetermined pitch between the pair of die;
forming an encapsulating material overlying a surface region of the plurality of die, and filling each of the regions defining the pitch to form an upper surface region of encapsulating material overlying an entirety of the plurality of die to seal each die bounded by a portion of the encapsulating material and a portion of the substrate member to cause formation of a panel structure encapsulating each of the plurality of die; and
releasing the substrate member to free the panel structure including the plurality of die;
exposing a backside of the panel structure to expose a portion of each of the plurality of die; and
forming a plurality of redistribution layers overlying the backside of the panel structure and configured to form an interconnection structure between each of the plurality of die and one or more contact pads configured from the redistribution layers.

2. The method of claim 1 wherein the one or more contact pads comprises one or more solder balls; wherein the substrate member is a carrier.

3. The method of claim 1 wherein the one or more pads comprises an overlying dielectric material.

4. The method of claim 1 wherein encapsulating material comprises an epoxy material, a polymer plastic material, a dielectric material, or glass material.

5. The method of claim 1 further comprising separating each of the packaged components using a saw blade, a scribe and break, or a laser ablation configured to a spacing based upon a package dimension of the die.

6. The method of claim 1 further comprising planarizing the upper surface region using a polishing process or a grinding process.

7. The method of claim 1 wherein the spatially disposing comprises a pick and place operation to move each die one by one from a first location to a location on the first side surface region.

8. The method of claim 1 wherein the plurality of die comprises at least 10,000 die or at least 100,000 die.

9. The method of claim 1 further comprising spatially disposing a plurality of die comprising a low noise amplifier configured on a silicon on insulating substrate onto a portion of the frontside surface.

10. The method of claim 1 further comprising spatially disposing a plurality of die comprising a low noise amplifier configured on a silicon on insulating substrate onto a portion of the frontside surface; and separating at least one die comprising the low noise amplifier and at least one die comprising the transformer to create a separate co-packaged chip device.

11. A panel scale packaging apparatus of a plurality of transformer devices, the apparatus comprising:
a plurality of die comprising a plurality of transformer devices spatially disposed in a predetermined pattern formed on a portion of the carrier member that has been released to achieve a fill factor of 70 percent and greater overlying the front side surface such that each pair of die are configured with a predetermined pitch between the pair of die;
an encapsulating material overlying a surface region of the plurality of die, and filling each of the regions defining the pitch to form an upper surface region of encapsulating material overlying an entirety of the plurality of die to seal each die bounded by a portion of the encapsulating material;
a backside surface comprising a portion of a plurality of transformer devices and released portion of the encapsulant material; and
a plurality of redistribution layers overlying the backside surface and configured to form an interconnection structure between each of the plurality of die and one or more contact pads configured from the redistribution layers.

12. The apparatus of claim 11 wherein the one or more contact pads comprises one or more solder balls.

13. The apparatus of claim 11 wherein the one or more pads comprises an overlying dielectric material.

14. The apparatus of claim 11 wherein encapsulating material comprises an epoxy material, a polymer plastic material, dielectric material, or glass material.

15. The apparatus of claim 11 wherein each of the die is configured to be separated using a saw blade, a scribe and break, or a laser ablation to a spacing based upon a package dimension of the die.

16. The apparatus of claim 11 wherein the upper surface region is characterized by a planarized surface configured using a polishing process or a grinding process.

17. The apparatus of claim 11 wherein the plurality of die comprises at least 10,000 die or at least 100,000 die arranged in an array.

18. The apparatus of claim 11 further comprising a plurality of die comprising a low noise amplifier configured on a silicon on insulating substrate spatially disposed within the encapsulant material to form a checker board pattern with the plurality of die comprising the transformer devices.

19. The apparatus of claim 11 wherein the plurality of redistribution layers are configured as a transformer device comprising a plurality of primary tracks and a plurality of secondary tracks.

20. A panel scale packaging apparatus of a plurality of transformer devices, the apparatus comprising:
a plurality of die comprising a plurality of transformer devices spatially disposed in a predetermined pattern formed on a portion of the carrier member that has been released to achieve a fill factor of 70 percent and greater overlying the front side surface such that each pair of die are configured with a predetermined pitch between the pair of die;
an encapsulating material overlying a surface region of the plurality of die, and filling each of the regions defining the pitch to form an upper surface region of encapsulating material overlying an entirety of the plurality of die to seal each die bounded by a portion of the encapsulating material;
a backside surface comprising a portion of a plurality of transformer devices and released portion of the encapsulant material;
a plurality of redistribution layers overlying the backside surface and configured to form an interconnection structure formed between each of the plurality of die and one or more contact pads configured from the redistribution layers; and
a plurality of transformer device comprising a plurality of primary tracks and a plurality of secondary tracks configured from a portion of the plurality of redistribution layers.
